(19) United States
(12) Patent Application Publication
(10) Pub. No.: US 2010/0031885 A1
(43) Pub. Date: Feb. 11, 2010

(54) Reactor For Growing Crystals

(76) Inventors: Claudio Pelosi, Parma (IT); Vittorio Pozzetti, Brugherio (IT); Natale Speciale, Paderno Dugnano (IT); Gianluca Valente, Milano (IT); Sonia De Angelis, Milano (IT); Danilo Crippa, Novara (IT); Franco Preti, Milano (IT)

Correspondence Address: Brannen Law Office, LLC;Nicholas A. Brannen, 104 S. Main Street, Suite #506, Fond du Lac, WI, 54935, US

(21) Appl. No.: 12/515,516

(22) PCT Filed: Nov. 11, 2007
(86) PCT No.: PCT/IB07/03434

§ 371 Date: May 19, 2009

(30) Foreign Application Priority Data
Nov. 20, 2006 (IT) MI2006A002213

(51) Int. Cl. C30B 25/10; C30B 25/08

(52) U.S. Cl. 118/719

(57) ABSTRACT

The present invention relates to a reactor (1) for growing crystals of a material, in particular of silicon carbide or a third-group nitride; it comprises a chamber (2) divided into a first zone (21) and a second zone (22), said division being accomplished through a dividing wall (3) having at least one opening (31) which puts said first and second zones (21,22) in communication with each other, injection means (41,42) adapted to supply said first zone (21) with at least one precursor gas of said material, exhaust means (5) adapted to discharge exhaust gases from said second zone (22), support means (6) located in said second zone (22) and adapted to support a growing crystal, and heating means (71,72) adapted to keep said first and second zones (21,22) at a temperature between 2000° C. and 2600° C.

This application is being filed in the United States for the national phase of international application number PCT/IB2007/003434 filed on 11 Nov. 2007 (publication number WO 2008/062269 A1), claiming priority on prior application MI2006A002213 filed in Italy 20 Nov. 2006, the contents of each being hereby incorporated herein by reference.

The present invention relates to a reactor for growing crystals, in particular of silicon carbide or a third-group nitride.

A reactor of this kind is known from patent EP0554047B1, although the description included therein is very schematic.

It is a reactor for growing silicon carbide crystals which comprises a reaction chamber divided into a first zone and a second zone, said division being accomplished through a dividing wall having a large funnel-shaped central opening putting the two zones in communication with each other; there are injection means adapted to supply the first zone with a gaseous mixture containing, among other constituents, a precursor gas of carbon (propane) and a precursor gas of silicon (silane), exhaust means adapted to discharge exhaust gases from the second zone, support means located in the second zone and adapted to support a growing crystal, and heating means adapted to heat both zones; the embodiment provides that during the growth processes the first zone is kept at a temperature between 1200° C. and 1400° C. and the second zone is kept at a temperature between 2000° C. and 2400° C.

This reactor has been conceived to provide a chemical reaction in the first zone, thus synthesizing silicon carbide in the form of solid particles (due to the low temperature of the first zone of the reactor); said solid particles of silicon carbide then move on to the second zone of the reactor, where they sublime (due to the high temperature of the second zone of the reactor).

This patent highlights the fact that graphite chamber walls tend to wear out and release carbon by evaporation and/or by reaction with silicon and/or silicon-based compounds into the high-temperature zones; for this reason, it is recommended not to use graphite walls, at least in the high-temperature zone.

Research and development activities carried out by the Applicant have dealt not only with the theoretical aspects pertaining to this type of reactors, but also with aspects relating to the practical implementation thereof.

In these reactors, in order not to cause defects in the structure of the grown crystal it is important that no particles, either liquid or solid, hit the crystalline growth seed or the growing crystal. This is certainly important when these crystals are grown for use in the microelectronics and optoelectronics industries (where crystals of very high purity and crystallographic quality are required), but it is also important when they are grown for use as gems, e.g. in the jewelry industry.

In these reactors, it is also important that the walls of the reaction chamber can withstand the extremely high temperatures and reactivity of precursor gases.

Finally, it is advantageous that the reactor structure, in particular of the reaction chamber, is as simple as possible so that its components, which are nonetheless subject to heavy operating conditions and requirements, can be designed more easily.

It is the object of the present invention to provide a reactor for growing crystals which in particular meets the above-mentioned requirements.

Said object is achieved by the reactor having the features set out in the appended claims.

The present invention is based on the idea of providing a reaction chamber divided into two zones by a dividing wall having at least one opening and of keeping both zones at high temperature, i.e. between 2000° C. and 2600° C.

In this manner, the reactivity of the precursor gases is at least partly neutralized.

The present invention will become more apparent from the following description and from the annexed drawings, wherein:

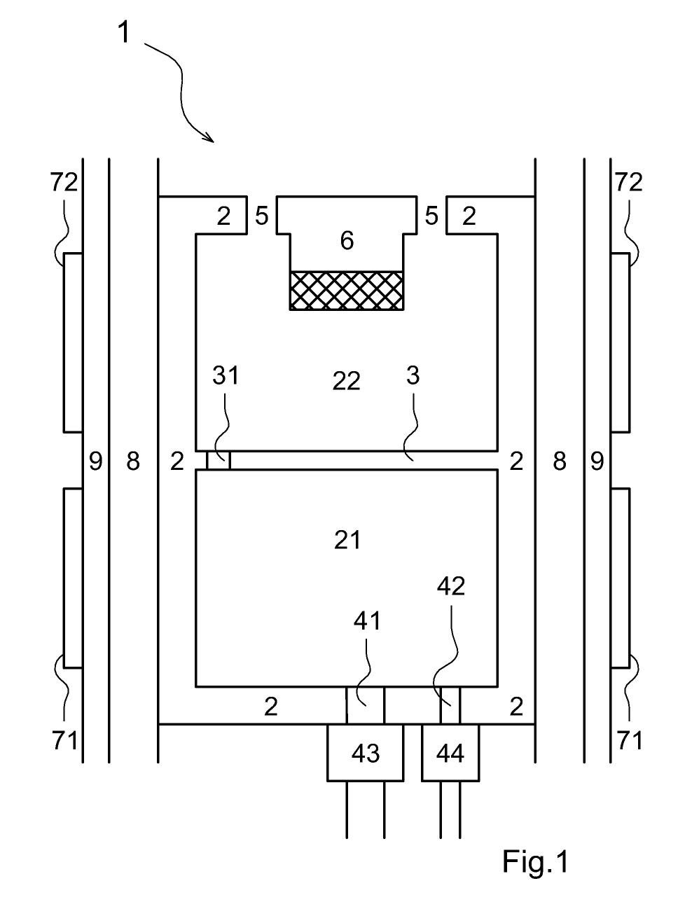

FIG. 1 shows a diagrammatic sectional view of a first reactor according to the present invention, and

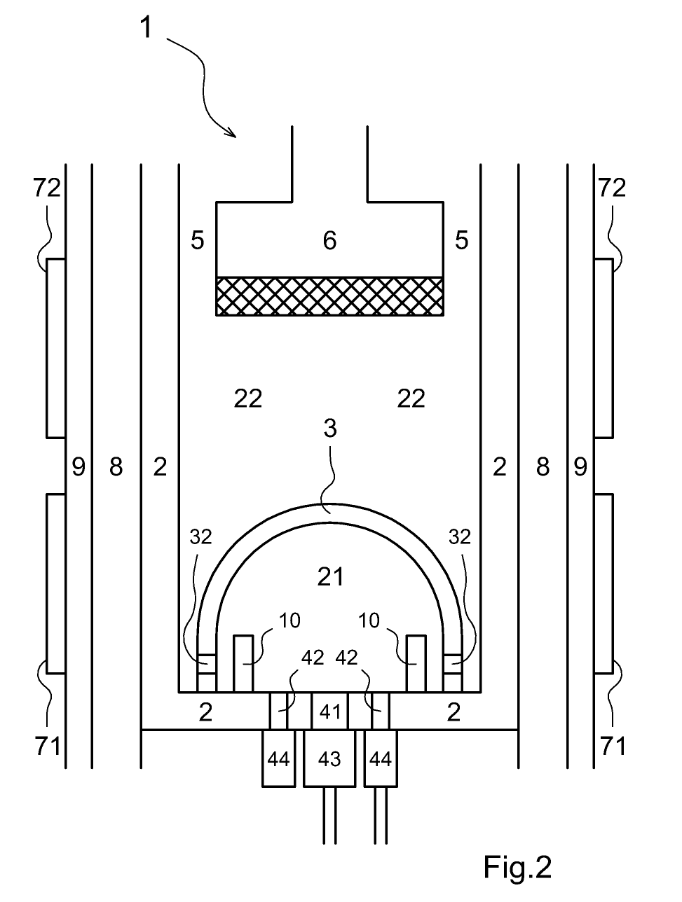

FIG. 2 shows a diagrammatic sectional view of a second reactor according to the present invention.

Said description and said drawings are to be considered as non-limiting examples.

In both figures, equivalent components of both reactors are referred to by the same reference numerals.

FIG. 1 shows a diagrammatic sectional view of a first reactor 1 according to the present invention for growing crystals of a material, in particular of silicon carbide or a third-group nitride (e.g. gallium nitride or, above all, aluminum nitride).

The reactor 1 comprises a reaction chamber 2 wherein the crystal growth takes place.

In the example of FIG. 1, the chamber 2 consists of a tube (having a circular cross-section) closed at the upper and lower ends by an upper disc and a lower disc, respectively; the tube and the discs are in particular made of graphite and are preferably coated with a layer of tantalum carbide on the inner side of the chamber.

The chamber 2 is divided into a first lower zone 21 (which defines a first volume) and a second upper zone 22 (which defines a second volume); the division between the two zones 21 and 22 is accomplished through a dividing wall 3.

In the example of FIG. 1, said wall consists of an intermediate disc, in particular made of graphite; both disc faces (upper and lower) are coated with a layer of silicon carbide.

The chamber 2 is inserted in a tube 8, the inner section of which substantially matches the outer section (in particular circular in shape) of the chamber tube; the tube 8 is made of thermo-insulating and refractory material, e.g. porous or fibrous graphite.

The tube 8 is inserted in another tube 9, the inner section of which substantially matches the outer section (in particular circular in shape) of the tube 8; the tube 9 acts as a tight container and is in particular made of quartz; in addition to ensuring good tightness, this material is also refractory (in fact, it can withstand temperatures up to 1200° C.).

The chamber 2 in the example of FIG. 1 is heated by electromagnetic induction. To this end, a first inductor 71 and a second inductor 72 are arranged around the tube 9; the inductor 71 is located below at the level of the zone 21, while the inductor 72 is located above at the level of the zone 22; this provides an easier separate control of the temperatures of the zones 21 and 22 to at least some extent. The heating means in the example of FIG. 1 are such that the chamber 2, in particular the zones 21 and 22, are kept at a very high temperature (not necessarily the same) between 2000° C. and 2600° C.

The lower disc of the chamber 2 has inlet openings 41 and 42 for supplying the precursor gases of the crystal material into the zone 21. In the example of FIG. 1, if the crystal is made of silicon carbide, the opening 41 can be used for supplying the precursor gas of silicon (e.g. SiH4, i.e. silane) and the opening 42 can be used for supplying the precursor gas of carbon (e.g. C2H4, i.e. ethylene, or C3H8, i.e. propane). Therefore, this is a separate inlet for two precursor gases; as an alternative, it may also be conceivable to use a single inlet for both precursor gases. It should be taken into account that said precursor gases are often mixed into a gaseous mixture comprising one or more carrier gases (e.g. hydrogen, helium, argon) and/or one or more other gases (e.g. hydrochloric acid, chlorine).

The gaseous flows are carried to the openings 41 and 42 through two respective ducts (only the final portions of which are shown in FIG. 1); at the end of said two ducts, there are two respective cooling means 43 and 44, the main function of which is cooling the precursor gases; this prevents the precursor gases (e.g. silane and/or ethylene) from dissociating, thus preventing any spurious deposits of material (e.g. silicon and/or carbon) from forming upstream of the inlet of the chamber 2. In the example of FIG. 1, the cooling means 43 and 44 are external to the chamber 2 and are shown in a very schematical manner. If a single gaseous flow is supplied into the chamber (mixture of different substances), it may suffice to employ only one opening and only one cooling means; this will apply whatever the number of zones in the chamber.

The intermediate disc 3 of the chamber 2 has at least one opening 31 which puts the zone 21 in communication with the zone 22; thus the crystal growth material can pass from the zone 21 to the zone 22.

The growth of the crystal takes place in the zone 22 of the chamber 2; for this purpose, at the upper disc of the chamber 2 there is a support element 6 adapted to support the growing crystal (schematized in the drawing as a rectangle with a criss-cross pattern). Typically, to the support element 6 a crystalline growth seed is fixed on which monocrystalline layers are subsequently epitaxially deposited to form a ingot-shaped single-crystal, i.e. having finite dimensions (from a few millimeters to some centimeters).

The upper disc of the chamber 2 has openings 5 for discharging the exhaust gases from the zone 22. In the example of FIG. 1, the openings 5 are adjacent to the support element 6.

In the example of FIG. 1, the openings 41 and 42 are not aligned with the opening 3, and the opening 3 is not aligned with the openings 5; this offset arrangement can improve the re-mixing of the gases within the reaction chamber, in particular in the zone 21 and in the zone 22.

The reactor of FIG. 2 is similar to the reactor of FIG. 1; therefore, only the differences between the two will be described below.

The dividing wall 3 is dome-shaped and rests on the lower disc of the chamber 2; the maximum outer diameter of said dome is somewhat smaller than the inner diameter of the tube of the chamber 2; near the lower disc of the chamber there is a set (e.g. six or eight or ten) of openings 32 in the wall 3; in the example of FIG. 1, the openings 32 are arranged substantially horizontally toward the tube of the chamber 2.

Reference numeral 42 designates a set (e.g. six) of openings in the lower disc of the chamber 2.

Reference numeral 44 designates an annular chamber suitably cooled by one or more gaseous and/or liquid flows; the chamber 44 communicates with the openings 42 and with a gaseous flow supply duct.

The support element 6 has a substantially cylindrical shape and is mounted to a shaft. Means are also provided for turning [rotary motion] and translating [linear motion] said shaft and thus also the support element with the associated crystal.

During the growth processes carried out in the reactor of FIG. 2, the crystal is typically kept turning and translated slowly upwards so that the crystalline layer deposition surface will substantially remain in the same position at all times; this may improve growth uniformity.

Reference numeral 5 designates an annular opening defined between the inner wall of the tube of the chamber 2 and the support element 6.

The reactor of FIG. 2 includes special means adapted to improve the mixing of the precursor gas coming from the opening 41 with the precursor gas coming from the openings 42 in the zone 21 of the chamber 2, under the dome 3.

Said means consist of a short tube 10, which rests on the lower disc of the chamber 2 and extends inside the zone 21 under the dome 3. The tube 10 surrounds the opening 41 as well as all other openings 42 and faces the openings 32; this avoids the creation of a direct path between the inlet openings and the outlet openings of the zone 21. In particular, the tube 10 is made of graphite and is preferably coated all over its surface with a layer of silicon carbide.

The reactor according to the present invention, in particular the examples of reactors described above and illustrated in FIG. 1 and FIG. 2, allows to dissociate the precursor gases in the reaction chamber only, to let them react in the first zone of the chamber without any formation of liquid or solid particles due to the high temperature of the first zone of the chamber, to carry (in a relatively slow and orderly manner) the compounds formed in the first zone of the chamber into the second zone of the chamber, and to obtain a good deposition of crystalline layers.

Since the precursor gases tend to react with each other as soon as they enter the chamber, their reactivity is at least partly neutralized, thereby protecting the walls of the reaction chamber from etching.

Furthermore, since precursor gases react with each other at high temperature, any formation of liquid or solid particles is essentially avoided.

Finally, since the precursor gases are kept cold until they enter the chamber, any premature dissociation leading to spurious deposits is essentially avoided as well.

The reactor according to the present invention (1 in the illustrated examples) is used for growing crystals of a material, in particular of silicon carbide or a third-group nitride. Said reactor has been conceived for growing ingot-shaped single-crystals by superposition of epitaxial monocrystalline layers.

In general, it comprises a chamber (2 in the illustrated examples) divided into a first zone (21 in the illustrated examples) and a second zone (22 in the illustrated examples); said division is accomplished through a dividing wall (3 in the illustrated examples) having at least one opening (31 and 32 in the illustrated examples) which puts the first and second zones in communication with each other; it also comprises injection means (41 and 42 in the illustrated examples) adapted to supply the first zone with at least one precursor gas of said material, exhaust means (5 in the illustrated examples) adapted to discharge exhaust gases from the second zone, support means (6 in the illustrated examples) located in the second zone and adapted to support a growing crystal, and heating means (71, 72 in the illustrated examples) adapted to keep the first and second zones at a temperature between 2000° C. and 2600° C.

Typically, the support means are adapted to support a crystalline seed at the beginning of the process and a grown crystal at the end of the process.

If the crystal material is a compound of at least a first substance and a second substance, the injection means may be adapted to supply said first zone with at least a first precursor gas of said first substance and at least a second precursor gas of said second substance; this is the case of both examples shown in the drawings.

In the case of silicon carbide, the precursor gas of carbon may be for example ethylene or propane, whereas the precursor gas of silicon may be for example silane. It may be appropriate to mix one or each precursor gas with other gases such as, for example, hydrogen and/or helium and/or argon and/or chlorine and/or hydrochloric acid.

The injection means may be adapted to supply said first precursor gas and said second precursor gas into the first zone separately; this is the case of both examples shown in the drawings. In this manner, the precursor gases will react with each other only when they are in the desired conditions within the reaction chamber.

Mixing means may advantageously be provided (10 in the example of FIG. 2) which are adapted to mix said first precursor gas with said second precursor gas in the first zone.

Moreover, shielding means may be provided (10 in the example of FIG. 2) which are adapted to avoid any direct path between the injection means and the openings in the dividing wall.

As can be understood from the above description, the mixing function and the shielding function may be provided by the same element(s); this is the case of the example of FIG. 2.

The heating means of the reactor are preferably adapted to keep the first zone at a temperature being higher than or equal to the temperature of the second zone. In particular, the reactor is adapted to maintain, during the growth processes, a temperature difference of 100-300° C. between the hottest point of the first zone (typically the lowest portion thereof) and any point of the second zone near the crystal (or preferably near the crystal deposition surface). This temperature difference promotes the transfer of the gaseous growth material from the first zone to the second zone, i.e. towards the crystal.

The reactor is preferably adapted to keep the first and second zones at essentially the same pressure, in particular between 1 mBar and 1,000 mBar, preferably between 100 mBar and 500 mBar. Of course, because there is a gaseous flow from the first zone to the second zone, the pressure cannot be exactly the same.

By providing a plurality of openings in the dividing wall for putting the first and second zones in communication with each other, it is possible to obtain a very uniform transfer of material from the first zone to the second zone.

The dividing wall can be provided in many different ways.

According to a first possibility, the dividing wall is dome-shaped and the openings are preferably located laterally; this is the case of the example of FIG. 2.

According to a second possibility, the dividing wall has a prism-like or cylinder-like shape and the openings are preferably located laterally.

According to a third possibility, the dividing wall is disc-shaped and the openings are preferably located in peripheral areas thereof; this is the case of the example of FIG. 1.

Many possibilities are available also as regards the shape of the chamber; however, the chamber typically has a prism-like or cylinder-like shape, preferably with a substantially vertical axis; this is the case of both examples shown in the drawings.

The openings in the dividing wall are preferably misaligned relative to the support means and/or to the injection means; this promotes the re-mixing of the gases in the chamber, in particular in the zones thereof; this is the case of both examples shown in the drawings.

As shown in the drawings, the first zone of the chamber (where the precursor gases enter) is located underneath the second zone of the chamber; it is thus unlikely that any liquid or solid particles can “fall” onto the crystal growth surface (which is located in the second zone, at the top end of the chamber).

As said, it is advantageous to use cooling means (43 and 44 in the illustrated examples) associated with the injection means (41 and 42 in the illustrated examples). If separate injection means are used, separate cooling means should be used as well; thus, the temperature of the two different gaseous flows can be kept under control more easily and more appropriately. All of the above considerations will apply whatever the number of zones in the chamber.

Since the temperatures of and within the reaction chamber are extremely high, the cooling means should be external to the chamber in order to be really effective.

As far as the materials used for the reactor components are concerned, the choice is not easy due to the high temperature and high reactivity of the substances and compounds involved; there are however a number of possibilities, the most typical and advantageous of which will be described below.

The dividing wall may be made essentially of graphite. Said wall may then be coated with a layer or plate of silicon carbide or tantalum carbide or niobium carbide or pyrolitic graphite.

As an alternative, the dividing wall may be made essentially of tantalum, in particular coated with a layer of tantalum carbide.

The chamber walls may be made essentially of graphite. Said walls may then be coated internally with a layer or plate of silicon carbide or tantalum carbide or niobium carbide or pyrolitic graphite.

As an alternative, the walls of said chamber may be made essentially of tantalum, in particular coated internally with a layer of tantalum carbide.

In order to improve the uniformity of the grown crystal, the support means are adapted to rotate and/or translate the growing crystal.

From an implementation viewpoint, a number of components can also be useful, such as a layer of thermo-insulating material (8 in the illustrated examples), a quartz container (9 in the illustrated examples), and induction-type heating means (7 in the illustrated examples); all of these components are used in the examples shown in the drawings.

The layer of thermo-insulating material surrounds the reactor chamber.

The reactor chamber is inserted in the quartz container (in particular a quartz tube); the layer of thermo-insulating material is preferably interposed between the chamber and the quartz container.

The heating means comprise one or more inductors wound around the quartz container.

1. Reactor for growing crystals of a material, in particular of silicon carbide or a third-group nitride, comprising a chamber divided into a first zone and a second zone, said division being accomplished through a dividing wall having at least one opening which puts said first and second zones in communication with each other, an injector supplying said first zone with at least one precursor gas of said material, an exhauster discharging exhaust gases from said second zone, a supporter located in said second zone and supporting a growing crystal, and a heater keeping said first and second zones at a temperature between 2000° C. and 2600° C.

2. Reactor according to claim 1, wherein said material is a compound of at least a first substance and a second substance, wherein said injector supplies said first zone with at least a first precursor gas of said first substance and at least a second precursor gas of said second substance.

3. Reactor according to claim 2, wherein said injector supplies said first precursor gas and said second precursor gas separately into said first zone.

4. Reactor according to claim 2, further comprising a mixer mixing said first precursor gas with said second precursor gas in said first zone.

5. Reactor according to claim 1, further comprising a shield that avoids establishing any direct path between said injector and said at least one opening in the dividing wall.

6. Reactor according to claim 1, wherein said said heater keeps said first zone at a temperature being higher than or equal to the temperature of said second zone.

7. Reactor according to claim 6, wherein a temperature difference of 100-300° C. between the hottest point of said first zone and any point of said second zone near said crystal is maintained.

8. Reactor according to claim 1, said first zone and said second zone are kept at essentially the same pressure, in particular between 1 mBar and 1000 mBar, preferably between 100 mBar and 500 mBar.

9. Reactor according to claim 1, wherein said wall has a plurality of openings which put said first zone and said second zone in communication with each other.

10. Reactor according to claim 1, wherein said dividing wall is dome-shaped and said openings are preferably located laterally.

11. Reactor according to claim 1, wherein said dividing wall has one of a prism-like and cylinder-like shape and said openings are preferably located laterally.

12. Reactor according to claim 1, wherein said dividing wall is disc-shaped and said openings are preferably located in peripheral areas.

13. Reactor according to claim 1, wherein said chamber has one of a prism-like and cylinder-like shape, preferably with a substantially vertical axis.

14. Reactor according to claim 1, wherein said openings are misaligned relative to at least one of said supporter and said injector.

15. Reactor according to claim 1, wherein said first zone is located underneath said second zone.

16. Reactor according to claim 1, further comprising a cooler associated with said injector.

17. Reactor according to claim 16, wherein said cooler is external to said chamber.

18. Reactor according to claim 16, comprising separate coolers for a first precursor gas and for a second precursor gas.

19. Reactor according to claim 1, wherein said dividing wall is made essentially of graphite.

20. Reactor according to claim 19, wherein said dividing wall is coated with one of a layer and a plate of one of silicon carbide and tantalum carbide and niobium carbide and pyrolitic graphite.

21. Reactor according to claim 1, wherein said dividing wall is made essentially of tantalum, in particular coated with a layer of tantalum carbide.

22. Reactor according to claim 1, wherein the walls of said chamber are made essentially of graphite.

23. Reactor according to claim 22, wherein the walls of said chamber are coated internally with one of a layer and plate of one of silicon carbide and tantalum carbide and niobium carbide and pyrolitic graphite.

24. Reactor according to claim 1, wherein the walls of said chamber are made essentially of tantalum, in particular coated internally with a layer of tantalum carbide.

25. Reactor according to claim 1, wherein said supporter one of rotates and translates the growing crystal.

26. Reactor according to claim 1, wherein said chamber is surrounded by a layer of thermo-insulating material.

27. Reactor according to claim 1, wherein said chamber is inserted in a quartz container, in particular a quartz tube.

28. Reactor according to claim 1, wherein said heater is an induction type heater.

29. Reactor according to claim 27, wherein said heater comprises at least one inductor wound around said quartz container.
